(19) United States
(12) Patent Application Publication
(10) Pub. No.: US 2011/0146578 A1
(43) Pub. Date: Jun. 23, 2011

(54) SUBSTRATE PROCESSING APPARATUS

(75) Inventor: Tomoshi Taniyama, Toyama (JP)

(73) Assignee: HITACHI-KOKUSAI ELECTRIC INC., Tokyo (JP)

(21) Appl. No.: 12/906,582

(22) Filed: Oct. 18, 2010

(30) Foreign Application Priority Data
Dec. 17, 2009 (JP) 2009-286279

(51) Int. Cl. C23C 16/02

(52) U.S. Cl. 118/725

(57) ABSTRACT

There are provided a substrate placing plate and a substrate processing apparatus using the substrate placing plate. The substrate processing apparatus comprises a process chamber configured to accommodate a substrate and perform a heat treatment on the substrate; and a substrate transfer machine configured to carry the substrate into the process chamber in a state where the substrate is placed on a substrate placing plate. The substrate placing plate comprises at least three substrate placing parts. The substrate placing parts are located on the same horizontal plane, and in a state where the substrate placing parts are located at a top side of the substrate placing plate, top surfaces of the substrate placing parts are higher than a surface of the substrate placing plate surrounded by the substrate placing parts and are higher than all peripheral surfaces of the substrate placing parts.

### CROSS-REFERENCE TO RELATED PATENT APPLICATION

This U.S. non-provisional patent application claims priority under 35 U.S.C. §119 of Japanese Patent Application No. 2009-286279, filed on Dec. 17, 2009, in the Japanese Patent Office, the entire contents of which are hereby incorporated by reference.

### BACKGROUND OF THE INVENTION

1. Field of the Invention

The present invention relates to a substrate processing apparatus configured to process a substrate such as a semiconductor wafer (hereinafter, referred to as a wafer), and more particularly, to a structure of a substrate placing plate (tweezers) used by a substrate transfer machine that carries a substrate in a substrate processing apparatus.

2. Description of the Related Art

When forming thin films on surfaces of substrates such as semiconductor wafers by a heat treatment such as a chemical vapor deposition (CVD) treatment, a vertical heat treatment apparatus including a process chamber configured to accommodate a boat in which wafers are held is used as a substrate processing apparatus. In the vertical heat treatment apparatus, wafers are carried from a wafer cassette or a front opening unified pod (FOUP) to the boat and accommodated in the boat by a wafer transfer machine.

FIG. 13 illustrates a structure of a substrate placing plate used by a conventional substrate transfer machine. FIG. 13 is a perspective view illustrating an example of a conventional substrate placing plate. FIG. 14A and FIG. 14B are a plan view and a side view of the substrate placing plate illustrated in FIG. 13. In FIG. 13, reference numeral 90 denotes the substrate placing plate, and reference numerals 91a and 91b denote substrate placing parts provided at the tip side of the substrate placing plate 90. Reference numerals 92a and 92b denote substrate placing parts provided at the base side of the substrate placing plate 90. The substrate placing parts 91a, 91b, 92a, and 92b are configured to support a substrate such as a wafer in a state where the substrate placing parts 91a, 91b, 92a, and 92b make contact with the peripheral part of the wafer.

However, since the above-mentioned exemplary conventional substrate placing plate supports the backside peripheral part of a wafer, the substrate placing plate makes contact with a CVD film formed on the backside peripheral part of the wafer, and thus undesired particles are generated. In addition, particularly, when a wafer having a diameter of 450 mm is placed, the amount of deflection of the wafer is undesirably great.

Referring to Patent Document 1, base-side placing parts and tip-side placing parts configured to place a wafer thereon, and base-side hooking parts and tip-side hooking parts configured to hook the peripheral part of the wafer are provided at tweezers so as to prevent misalignment of the wafer when the wafer is picked up from a pod.

[Patent Document 1] Japanese Unexamined Patent Application Publication No. 2007-250797

### SUMMARY OF THE INVENTION

An object of the present invention is to provide a substrate placing plate that cannot make contact with the backside peripheral part of a wafer when the wafer is placed on the substrate placing plate or that can reduce the amount of wafer deflection particularly when a large wafer such as a wafer having a diameter of 450 mm is placed on the substrate placing plate, and a substrate processing apparatus using the substrate placing plate.

According to an aspect of the present invention, there is provided a substrate processing apparatus comprising: a process chamber configured to accommodate a substrate and perform a heat treatment on the substrate; and

a substrate transfer machine configured to carry the substrate into the process chamber in a state where the substrate is placed on a substrate placing plate,

wherein the substrate placing plate comprises at least three substrate placing parts, and

the at least three substrate placing parts are located on the same horizontal plane, and in a state where the at least three substrate placing parts are located at a top side of the substrate placing plate, top surfaces of the at least three substrate placing parts are higher than a surface of the substrate placing plate surrounded by the at least three substrate placing parts and are higher than all peripheral surfaces of the at least three substrate placing parts.

### BRIEF DESCRIPTION OF THE DRAWINGS

FIG. 1 is a perspective view illustrating a substrate processing apparatus according to an embodiment of the present invention.

FIG. 2 is a vertical sectional view illustrating a process furnace of the substrate processing apparatus according to the embodiment of the present invention.

FIG. 3 is a side view illustrating a substrate transfer machine according to the embodiment of the present invention.

FIG. 4 is a perspective view illustrating a substrate placing plate according to the embodiment of the present invention.

FIG. 5A, FIG. 5B, and FIG. 5C are a plan view, a side view, and a rear view illustrating the substrate placing plate according to the embodiment of the present invention.

FIG. 6A to FIG. 6F are partial sectional views illustrating the substrate placing plate according to the embodiment of the present invention.

FIG. 7A and FIG. 7B are schematic sectional views illustrating the substrate placing plate according to the embodiment of the present invention.

FIG. 8 is a view illustrating the case where a wafer having a diameter of 450 mm is supported at four points.

FIG. 9 is a view illustrating the amount of deflection of the wafer having a diameter of 450 mm when the wafer is supported at four points.

FIG. 10 is an enlarged view of a part of FIG. 9.

FIG. 11 is a view illustrating four support points of a boat by which a wafer having a diameter of 450 mm is supported at the four points.

FIG. 12 is a view illustrating an entrance region of a pod for a substrate placing plate.

FIG. 13 is a perspective view illustrating an example of a conventional substrate placing plate.

FIG. 14A and FIG. 14B are a plan view and a side view illustrating the conventional substrate placing plate.

### DETAILED DESCRIPTION OF THE PREFERRED EMBODIMENTS

Hereinafter, an embodiment of the present invention will be described with reference to the attached drawings.

[Overview of Substrate Processing Apparatus]

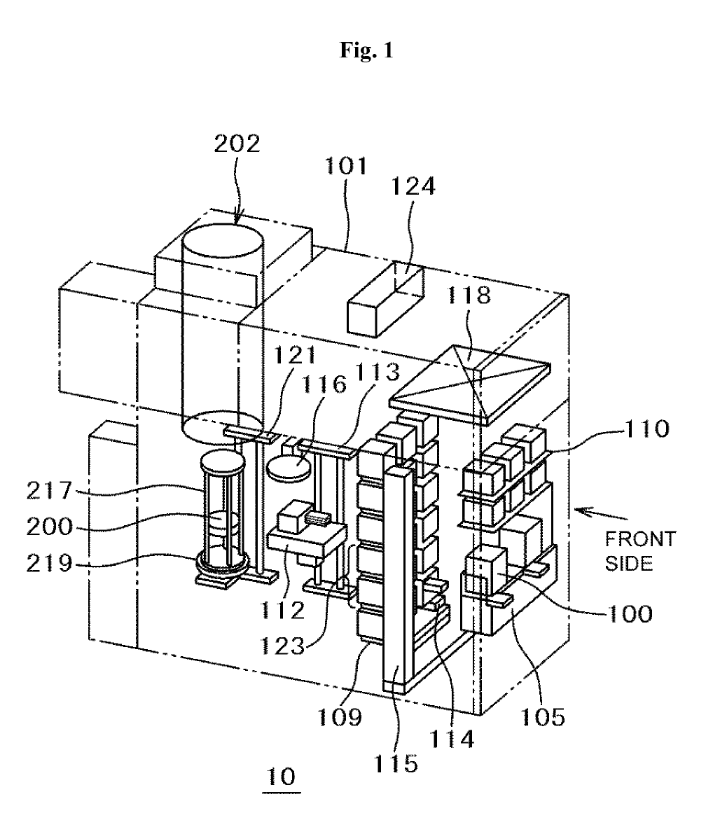

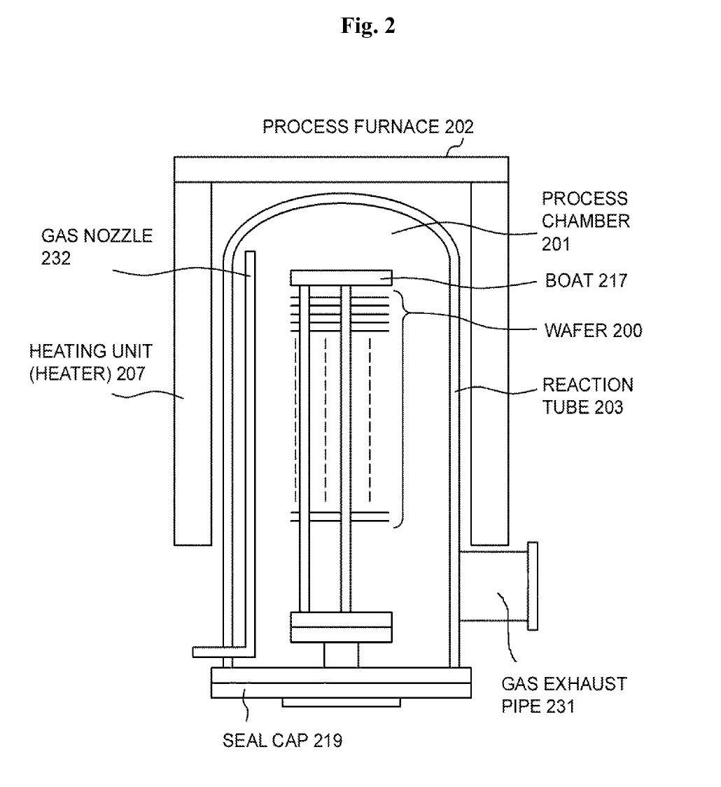

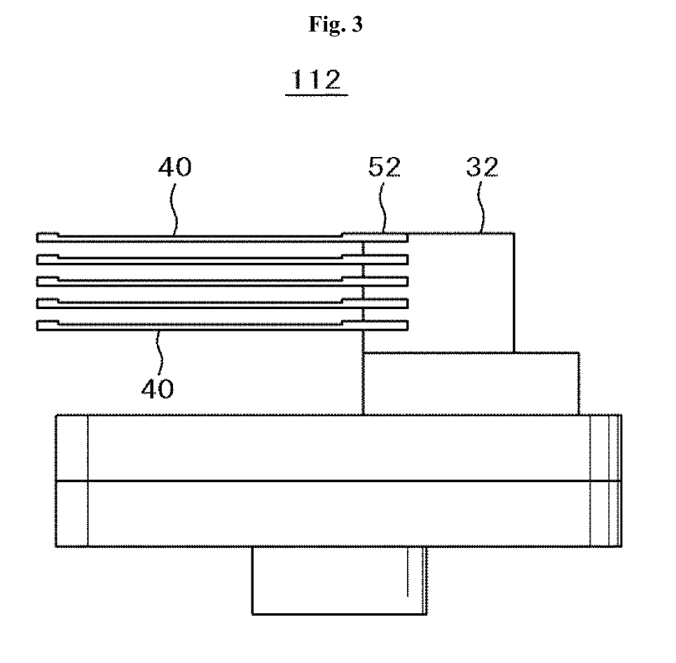

First, with reference to FIG. 1, FIG. 2, and FIG. 3, a substrate processing apparatus 10 will be schematically explained according to the embodiment of the present invention. FIG. 1 is a perspective view illustrating the substrate processing apparatus 10 according to the embodiment of the present invention. FIG. 2 is a vertical sectional view illustrating a process furnace 202 of the substrate processing apparatus 10 according to the embodiment of the present invention. FIG. 3 is a side view illustrating a substrate transfer machine 112 according to the embodiment of the present invention.

As shown in FIG. 1, at a front inner side of a case 101 of the substrate processing apparatus 10, a cassette stage 105 is installed. Between the cassette stage 105 and an external carrying device (not shown), cassettes 100 which are substrate containers are transferred. At the backside of the cassette stage 105, a cassette carrying machine 115 is installed. At the backside of the cassette carrying machine 115, a cassette shelf 109 is installed to store cassettes 100. In addition, at the upper side of the cassette stage 105, a standby cassette shelf 110 is installed to store cassettes 100. At the upper side of the standby cassette shelf 110, a cleaning unit 118 is installed. The cleaning unit 118 is provided to circulate clean air in the case 101.

At the rear upper side of the case 101, the process furnace 202 is installed. At the lower side of the process furnace 202, a boat elevator 121 is installed. The boat elevator 121 raises a boat 217 in which wafers 200 are held to the inside of the process furnace 202 and lowers the boat 217 from the inside of the boat 217. The boat 217 is a substrate holding tool configured to hold wafers 200 horizontally in multiple stages. At the boat elevator 121, a seal cap 219 is installed as a cover configured to close the bottom side of the process furnace 202. The seal cap 219 supports the boat 217 vertically.

Between the boat elevator 121 and the cassette shelf 109, the wafer transfer machine (substrate transfer machine) 112 is installed to carry wafers 200. As shown in FIG. 3, in the current embodiment, a plurality of substrate placing plates 40 are installed at the wafer transfer machine 112 in a manner such that the substrate placing plates 40 are laid over each other in a vertical direction with predetermined intervals therebetween. Alternatively, only one substrate placing plate 40 may be installed at the wafer transfer machine 112. Beside the boat elevator 121, a furnace port shutter 116 is installed to hermetically close the bottom side of the process furnace 202. When the boat 217 is placed outside the process furnace 202, the bottom side of the process furnace 202 may be closed by the furnace port shutter 116.

Cassettes 100 in which wafers 200 are charged are carried to the cassette stage 105 by the external carrying device (not shown). In addition, the cassettes 100 are carried from the cassette stage 105 to the cassette shelf 109 or the standby cassette shelf 110 by the cassette carrying machine 115. At the cassette shelf 109, a transfer shelf 123 is provided to store cassettes 100 which are carrying objects of the wafer transfer machine 112. Cassettes 100 are transferred to the transfer shelf 123 by the cassette carrying machine 115 so as to transfer wafers 200 from the cassettes 100 to the boat 217. After the cassettes 100 are transferred to the transfer shelf 123, wafers 200 are transferred by the wafer transfer machine 112 from the cassettes 100 of the transfer shelf 123 to the boat 217 in a state where the boat 217 is moved downward.

After a predetermined number of wafers 200 are transferred into the boat 217, the boat 217 is loaded into the process furnace 202 by the boat elevator 121, and the process furnace 202 is hermetically closed by the seal cap 219. In the hermetically closed process furnace 202, the wafers 200 are heated, and along with this, a process gas is supplied into the process furnace 202 so as to perform a process such as a heating process on the wafers 200.

After the wafers 200 are processed, in the reverse order to the order of the above-described operations, the wafers 200 are transferred from the boat 217 to the cassettes 100 of the transfer shelf 123 by the wafer transfer machine 112, and the cassettes 100 are transferred from the transfer shelf 123 to the cassette stage 105 by the cassette carrying machine 115. Then, the cassettes 100 are carried to the outside of the case 101 by the external carrying device (not shown).

When the boat 217 is moved downward, the furnace port shutter 116 closes the bottom side of the process furnace 202 hermetically so that outside air cannot enter the process furnace 202.

In the above-described example, cassettes are used as wafer containers. However, alternatively, pods may be used as wafer containers.

[Process Chamber]

As shown in FIG. 1 and FIG. 2, according to the current embodiment, the substrate processing apparatus 10 includes the process furnace 202, and the process furnace 202 includes a reaction tube 203 made of quartz. The reaction tube 203 is a reaction vessel configured to accommodate substrates (in the current embodiment, wafers 200) and process the substrates. The reaction tube 203 is installed in a heating unit (in the current embodiment, a resistance heater) 207. A bottom opening of the reaction tube 203 can be hermetically closed by the seal cap 219 in a state where a sealing member (not shown) is disposed between the reaction tube 203 and the seal cap 219.

The heater 207, the reaction tube 203, and the seal cap 219 constitute the process furnace 202. In addition, the reaction tube 203 and the seal cap 219 constitute a process chamber 201. The substrate holding tool (boat) 217 is erected on the seal cap 219. The boat 217 is configured to be inserted into the process furnace 202 through a bottom opening of the process furnace 202. In the boat 217, a plurality of wafers 200 to be batch processed are horizontally held and piled in multiple stages in the axial direction (vertical direction) of the boat 217. The heater 207 is used to heat the wafers 200 inserted in the process furnace 202 to a predetermined temperature.

[Gas Supply System]

As shown in FIG. 2, a gas nozzle 232 is installed at the sidewall of the reaction tube 203 as a gas supply system configured to supply a source gas to the process chamber 201. The gas nozzle 232 is installed in a manner such that an end of the gas nozzle 232 penetrates a lower part of the reaction tube 203 in a horizontal direction, and a source gas is supplied to the end of the gas nozzle 232 from a source gas supply source (not shown) through a flow rate control unit such as a mass flow controller (MFC) and an on-off valve. A source gas supplied to the gas nozzle 232 is introduced into the process chamber 201 through the other end of the gas nozzle 232 and a plurality of holes formed in the gas nozzle 232.

At the center part in the reaction tube 203, the boat 217 in which a plurality of wafers 200 are placed in multiple stages at the same interval is placed, and the boat 217 is configured to be moved into and out of the reaction tube 203 by the boat elevator 121 (refer to FIG. 1).

[Exhaust Unit]

An end of an exhaust pipe 231 is connected to the process chamber 201 to exhaust gas from the inside of the process chamber 201. The other end of the exhaust pipe 231 is connected to a vacuum pump (exhaust device) (not shown) through an auto pressure controller (APC) valve. The inside of the process chamber 201 is vacuum-evacuated by the vacuum pump.

[Boat]

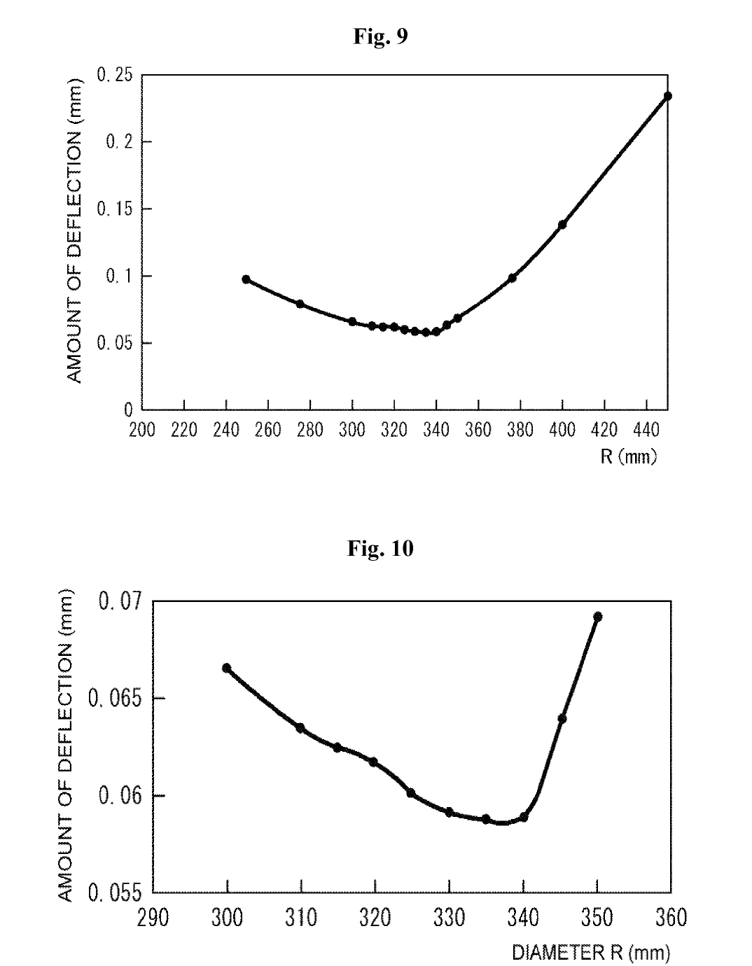

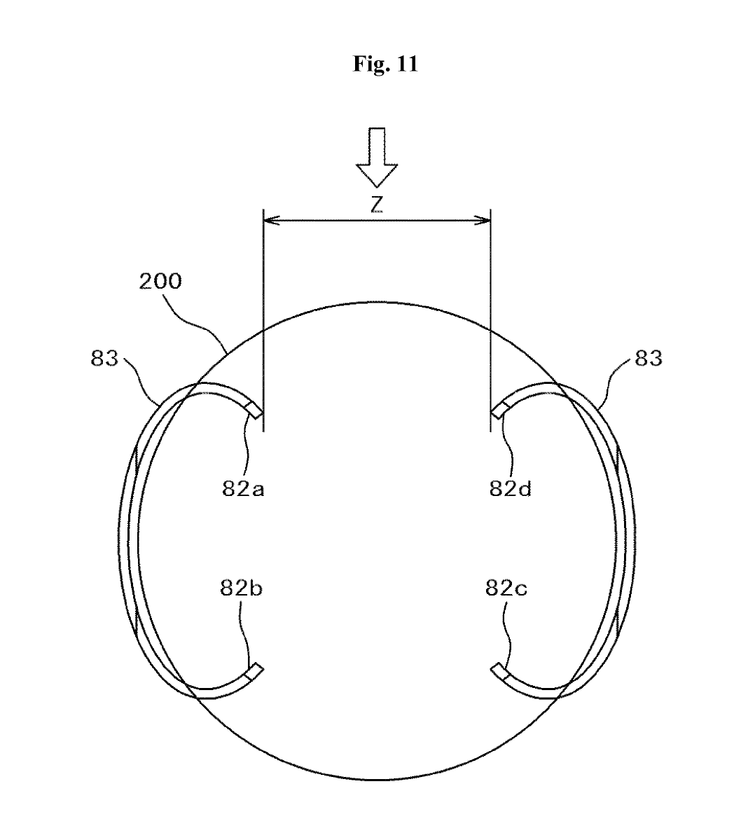

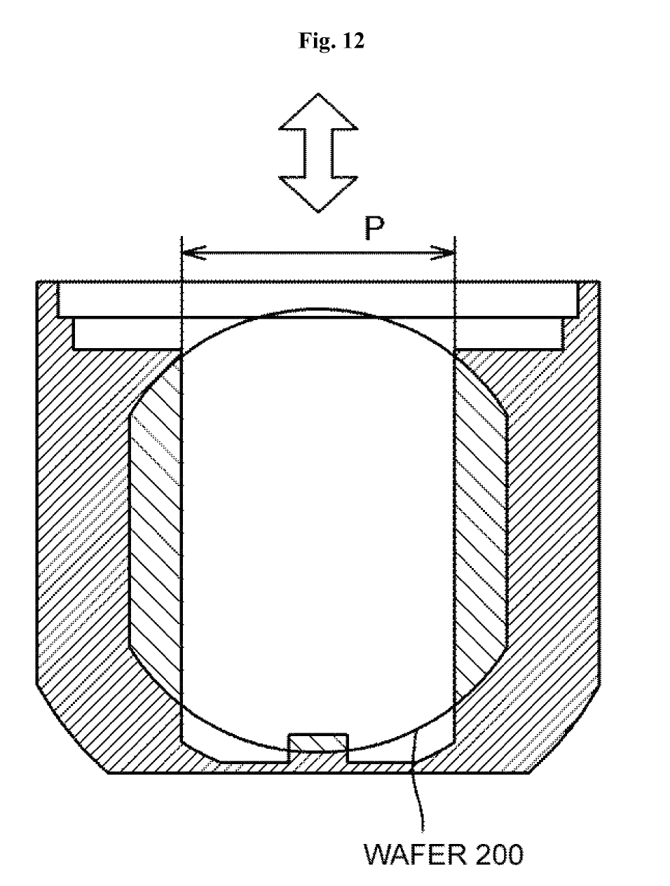

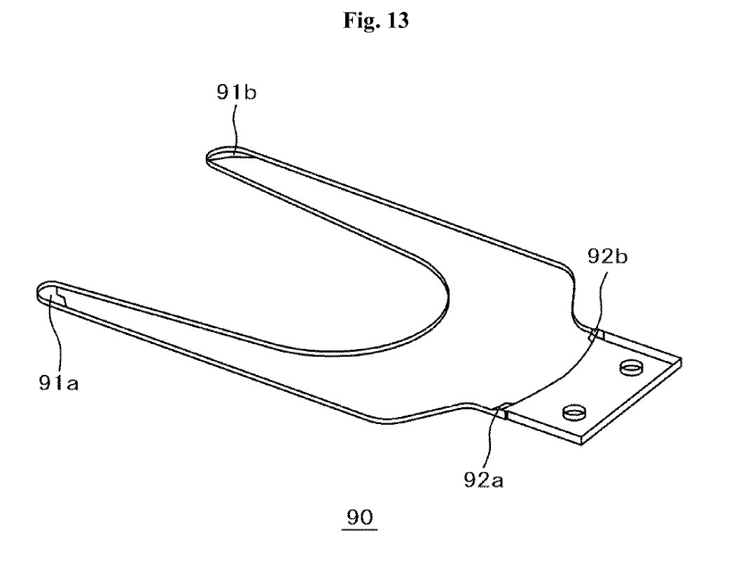

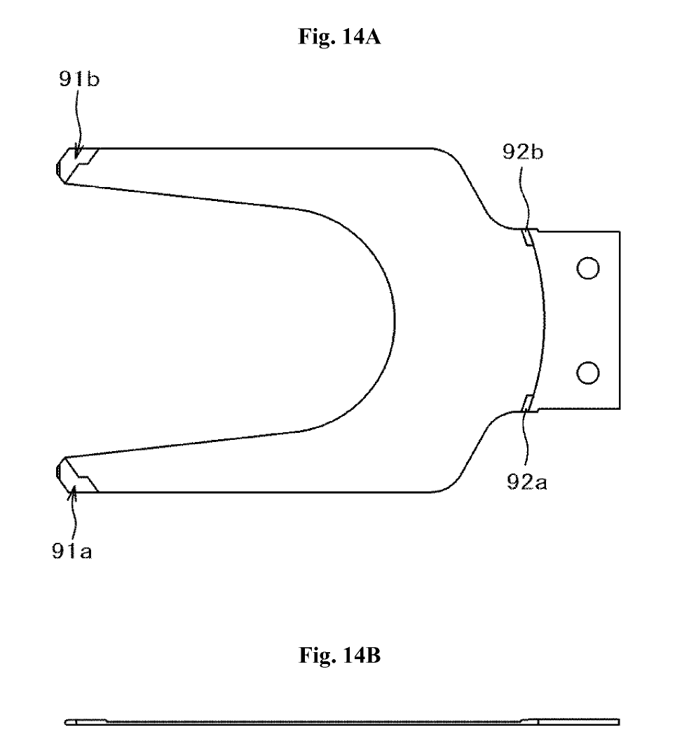

Next, the structure of the boat 217 will be described according to the embodiment of the present invention with reference to FIG. 8 to FIG. 11. FIG. 8 is a view illustrating the case where a wafer having a diameter of 450 mm is supported at four points. FIG. 9 is a view illustrating the amount of deflection of the wafer having a diameter of 450 mm when the wafer is supported at four points. FIG. 10 is an enlarged view of a part of FIG. 9. FIG. 11 is a view illustrating four support points of the boat 217 by which the wafer having a diameter of 450 mm is supported, for explain the relationship with wafer support positions of the substrate placing plate of the embodiment of the present invention.

In FIG. 8, reference numerals 81a, 81b, 81c, and 81d denote four support points on which a wafer 200 having a diameter of 450 mm is supported. R denotes the diameter of a circle the radius of which is defined from each of the support points to the center of the wafer 200. X denotes angles between the support points, and it is learned from an experiment that the amount of deflection of the wafer 200 is minimal when the support points are uniformly arranged (X=90 degrees). FIG. 9 illustrates the amount of deflection of the wafer 200 of FIG. 8 when the diameter R is varied. FIG. 10 is an enlarged view of a part of FIG. 9. Referring to FIG. 10, it can be understood that the amount of deflection is minimal when R ranges between 320 mm and 340 mm. Therefore, as shown in FIG. 11, wafer support tools 83 are installed at the boat 217 in a manner such that four support parts 82a, 82b, 82c, and 82d configured to support the wafer 200 are arranged in the range from R=320 mm to R=340 mm. In FIG. 11, the arrow denotes an approach direction of the wafer 200. In detail, in the range from R=320 mm to R=340 mm, the four support parts 82a, 82b, 82c, and 82d of the wafer support tools 83 are shaped like a straight line pointed toward the center of the wafer 200. While being bent toward a horizontal direction (transversal direction) from a position where R=340 mm, the wafer support tools 83 face the outer circumference of the wafer 200. As a result, the wafer support tools 83 have an approximately C shape.

In the wafer support tools 83, only the four support parts 82a, 82b, 82c, and 82d have a shape (island shape) higher than the other parts. As a result, it can be prevented that any other part than the four support parts 82a, 82b, 82c, and 82d of the wafer support tools 83 makes contact with the wafer 200. The boat 217 is configured by fixing the wafer support tools 83 to three or four pillars of a well-known boat.

At R=320 mm, the distance (Z) between the support parts 82a and 82d is about 220 mm. The gap between the support parts 82a and 82d is an entrance region for the substrate placing plate 40. Therefore, when a clearance (margin) of 10 mm is considered at both sides of the substrate placing plate 40, it may be necessary to adjust the width of the substrate placing plate 40 to 200 mm or smaller.

[Pod]

Next, in a pod configured to accommodate wafers having a diameter of 450 mm, an entrance region for the substrate placing plate 40 will be explained with reference to FIG. 12. FIG. 12 is a top view of the pod, and the side parts and inner parts of a wafer 200 are supported by parts such as sidewalls of the pod. As shown by the arrow at the upper part of FIG. 12, it is configured such that the wafer 200 can be put into the pod and taken out of the pod. Therefore, since the substrate placing plate 40 enters from the upper side, if the width (p) of the entrance region for the substrate placing plate 40 is, for example, 270 mm or greater, it is necessary to adjust the width of the substrate placing plate 40 to 250 mm or smaller in the case where a clearance (margin) of 10 mm is considered at both sides of the substrate placing plate 40.

[Substrate Placing Plate]

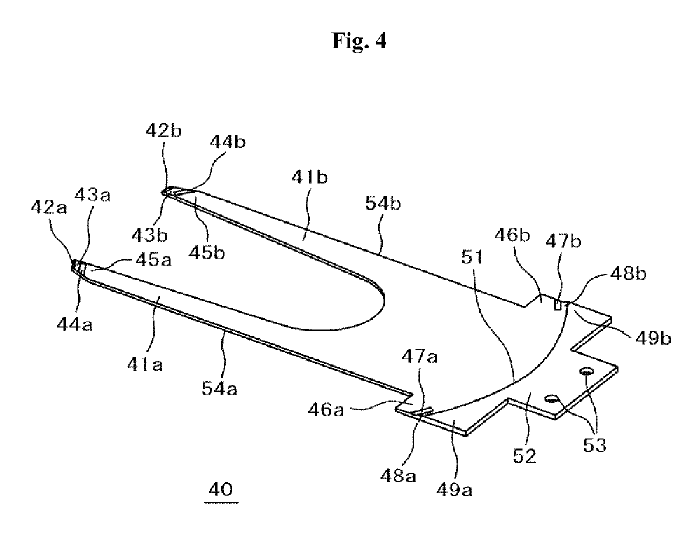

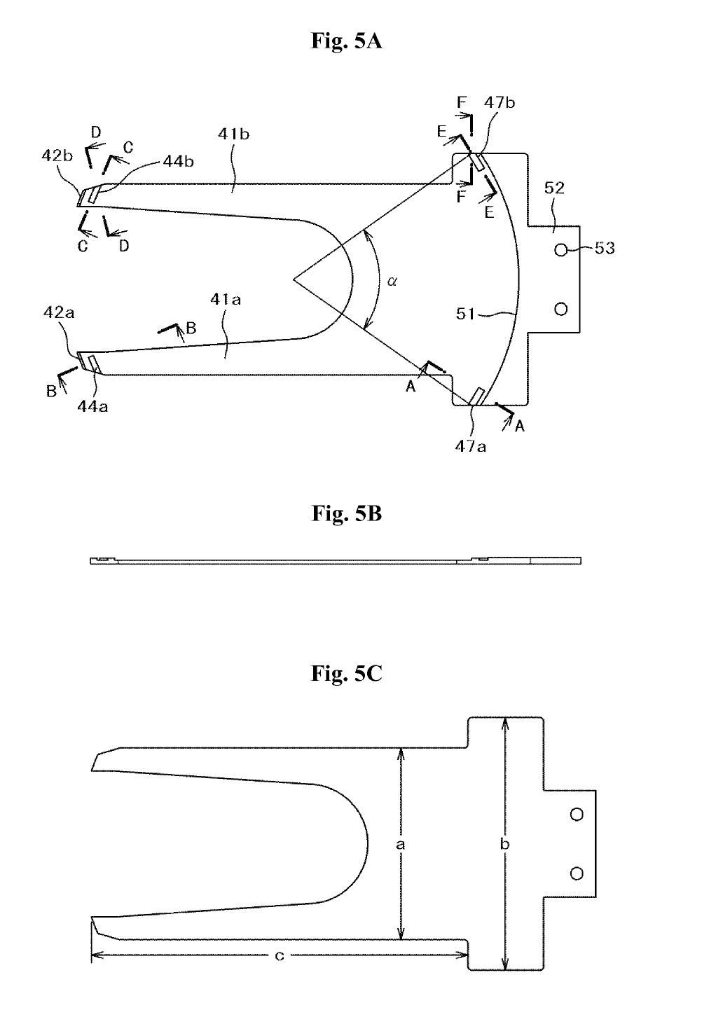

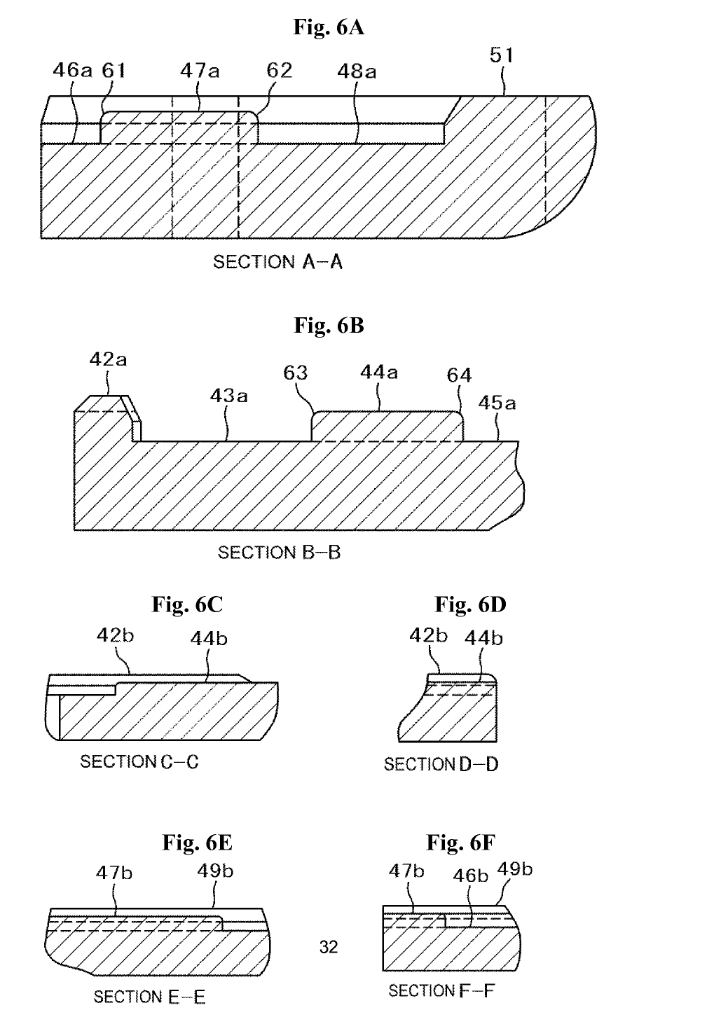

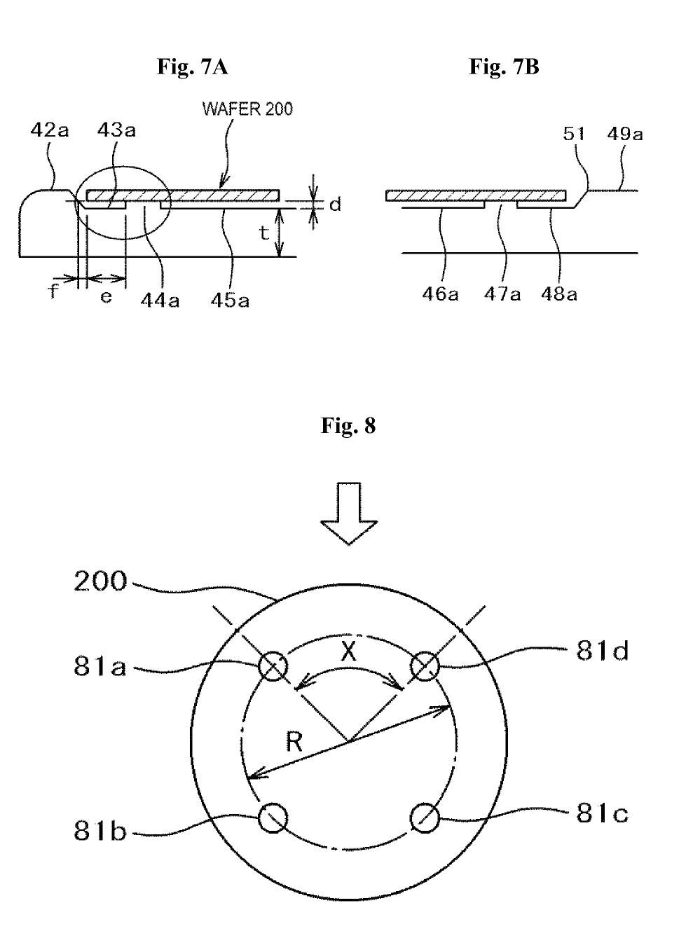

Next, the structure of the substrate placing plate 40 will be described with reference to FIG. 4 to FIG. 7 according to the embodiment of the present invention. FIG. 4 is a perspective view illustrating the substrate placing plate 40 according to the embodiment of the present invention. FIG. 5A, FIG. 5B, and FIG. 5C are a plan view, a side view, and a rear view illustrating the substrate placing plate 40 according to the embodiment of the present invention. FIG. 6A to FIG. 6F are partial sectional views illustrating the substrate placing plate 40 according to the embodiment of the present invention. FIG. 6A, FIG. 6B, FIG. 6C, FIG. 6D, FIG. 6E, and FIG. 6F are sectional views taken along lines A-A, B-B, C-C, D-D, E-E, and F-F of FIG. 5A, respectively. FIG. 7A and FIG. 7B are schematic sectional views illustrating the substrate placing plate 40 according to the embodiment of the present invention. FIG. 7A illustrates the tip side of the substrate placing plate 40, and FIG. 7B illustrates the base side of the substrate placing plate 40. Preferably, the substrate placing plate 40 may be made of one or more materials selected from alumina, carbon, SiC, and quartz.

As shown in FIG. 4 to FIG. 5C, according to the embodiment of the present invention, the substrate placing plate 40 has a two-pronged fork shape in which a sheet-shaped plate is divided into two arms 41a and 41b extending from a tip side to a base side. At the tip side of the substrate placing plate 40, tip-side position misalignment prevention parts 42a and 42b are provided to prevent misalignment of a wafer 200 placed on the substrate placing plate 40, and tip-side substrate placing parts 44a and 44b are provided to support the bottom side of the wafer 200.

At the base side of the substrate placing plate 40, an installation part 52 is provided to fix the substrate placing plate 40 to a substrate placing part fixing part 32 of the wafer transfer machine 112; a base-side position misalignment prevention parts 51 is provided to prevent misalignment of a wafer 200 placed on the substrate placing plate 40; and base-side substrate placing parts 47a and 47b are provided to support the bottom side of the wafer 200. The installation part 52 includes installation holes 53.

The four substrate placing parts 44a, 44b, 47a, and 47b are located on the same horizontal plane, and in a state where the four substrate placing parts 44a, 44b, 47a, and 47b are located at the top side of the substrate placing plate 40, the top surfaces of the four substrate placing parts 44a, 44b, 47a, and 47b are higher than a surface of the substrate placing plate 40 surrounded by the four substrate placing parts 44a, 44b, 47a, and 47b and are higher than all the peripheral surfaces of the four substrate placing parts 44a, 44b, 47a, and 47b.

In the above-described embodiment, four substrate placing parts are used. However, only one tip-side substrate placing part may be used. That is, totally three substrate placing parts may be used.

As shown in FIG. 6B, the tip-side substrate placing part 44a is higher than surrounding surfaces 43a and 45a. In addition, the upper part of the tip-side substrate placing part 44a is flat, and edges 63 and 64 are rounded. That is, the tip-side substrate placing part 44a includes a substrate placing surface for placing a substrate thereon, and surfaces rising from the surfaces 43a and 45a of the substrate placing plate 40 to the substrate placing surface. The edges between the rising surfaces and the substrate placing surface are rounded. The tip-side position misalignment prevention part 42a includes a vertical surface vertically extending from the surface 43a of the substrate placing plate 40, a rising inclined surface extending from the vertical surface to the tip side, an upper flat surface part extending from the rising inclined surface, and a falling inclined surface extending from the upper flat surface part toward the tip side. Owing to the above-described inclined surfaces, movement of a wafer 200 can be restricted.

In addition, as shown in FIG. 6A, the base-side substrate placing part 47a is higher than surrounding surfaces 46a and 48a. In addition, the upper part of the base-side substrate placing part 47a is flat, and edges 61 and 62 are rounded. That is, the base-side substrate placing part 47a includes a substrate placing surface for placing a substrate thereon, and surfaces rising from the surfaces 46a and 48a of the substrate placing plate 40 to the substrate placing surface. The edges between the rising surfaces and the substrate placing surface are rounded. The base-side position misalignment prevention part 51 includes a vertical surface vertically extending from the surface 48a of the substrate placing plate 40, a rising inclined surface extending from the vertical surface to the base side, and an upper flat surface part extending from the rising inclined surface. Owing to the above-described inclined surfaces, movement of a wafer 200 can be restricted.

The tip-side substrate placing part 44b and the base-side substrate placing part 47b have the same structures as those of the tip-side substrate placing part 44a and the base-side substrate placing part 47a.

Outer sides 54a and 54b of the two arms 41a and 41b are parallel with each other, and in the current embodiment, the length (c) (refer to FIG. 5C) of the outer sides 54a and 54b is about 370 mm. If the outer sides 54a and 54b are not parallel with each other, for example, if the outer sides 54a and 54b have a tapered shape, the width (a) between the outer sides 54a and 54b is increased, and if the width (a) becomes greater than the width (p) of the entrance region of the pod, it is difficult to insert the substrate placing plate 40 into the pod.

In addition, as shown in FIG. 5C, the width (b) of a base side where the base-side substrate placing parts 47a and 47b are located is greater than the width (a) between the outer sides 54a and 54b. In this case, the angle (α) between an imaginary line drawn from the base-side substrate placing part 47a to the center of a wafer and an imaginary line drawn from the base-side substrate placing part 47b to the center of the wafer can be 60 degrees or greater. Therefore, the amount of deflection of a wafer can be reduced.

When the substrate placing plate 40 is inserted into the boat 217, for example, as shown by the arrow of FIG. 11, the two arms 41a and 41b of the substrate placing plate 40 is inserted between the support parts 82a and 82d but the base side of the substrate placing plate 40 where the base-side substrate placing parts 47a and 47b are located is not inserted between the support parts 82a and 82d.

However, when the substrate placing plate 40 is inserted into the pod, the two arms 41a and 41b of the substrate placing plate 40, and the base side of the substrate placing plate 40 where the base-side substrate placing parts 47a and 47b are located are inserted into the entrance region (p) of the pod (refer to FIG. 12). Therefore, in the current embodiment, the width (a) and (b) shown in FIG. 5C are set as follows. The width (a) between the outer sides 54a and 54b of the two arms 41a and 41b is set to 200 mm which is a maximum width insertable between the support parts 82a and 82d of the boat 217 shown in FIG. 11, and the width (b) of the base side is set to 250 mm which is a maximum width insertable into the entrance region (p) of the pod shown in FIG. 12.

As shown schematically in FIG. 7A and FIG. 7B, the tip-side position misalignment prevention part 42a and the base-side position misalignment prevention part 51 are higher than the tip-side substrate placing part 44a and the base-side substrate placing part 47a. Similarly, the tip-side position misalignment prevention part 42b and the base-side position misalignment prevention part 51 are higher than the tip-side substrate placing part 44b and the base-side substrate placing part 47b. Owing to this height difference, position misalignment of a wafer 200 can be prevented by the tip-side position misalignment prevention parts 42a and 42b and the base-side position misalignment prevention part 51.

In addition, like the surfaces 43a and 45a, all the surrounding areas of the tip-side substrate placing part 44a are lower than the tip-side substrate placing part 44a. The surrounding areas of the tip-side substrate placing part 44b are also lower than the tip-side substrate placing part 44b like in the case of the tip-side substrate placing part 44a. In addition, like the surfaces 46a and 48a, all the surrounding areas of the base-side substrate placing part 47a are lower than the base-side substrate placing part 47a. The surrounding areas of the base-side substrate placing part 47b are also lower than the base-side substrate placing part 47b like in the case of the base-side substrate placing part 47a. That is, the tip-side substrate placing parts 44a and 44b, and the base-side substrate placing parts 47a and 47b have island shapes higher than surrounding areas along all peripheries. The upper parts of the substrate placing parts 44a, 44b, 47a, and 47b are flat.

In this way, parts such as the substrate placing parts 44a and 47a are higher than their surrounding areas such as the surfaces 43a and 48a so that the backside peripheral part of a wafer 200 may not be brought into contact with the substrate placing plate 40.

Preferably, the height (d) of the substrate placing parts 44a, 44b, 47a, and 47b may be in the range from 1 mm to 1.5 mm. In other words, when a wafer 200 is placed on the substrate placing plate 40, the distance (d) between the backside of the wafer 200 and surfaces such as the surface 45a (concave part) of the substrate placing plate 40 may be in the range from 1 mm to 1.5 mm. To process more wafers 200 at a time, it is necessary to decrease the gap (pitch) between wafers 200 stacked in the boat 217. For this, it is preferable to decrease the thickness (t) and distance (d) of the substrate placing plate 40. However, if the distance (d) is decreased, a wafer 200 may make contact with the substrate placing plate 40. Thus, it may be preferable that the distance (d) is in the range from 1 mm to 1.5 mm.

Furthermore, in the current embodiment, when a wafer 200 is placed, the positions of the tip-side substrate placing parts 44a and 44b and the base-side substrate placing parts 47a and 47b are spaced apart from the edge of the wafer 200 by 5 mm or greater. Referring to FIG. 7A and FIG. 7B, since there is a gap (f) between the edge of the wafer 200 and the tip-side position misalignment prevention part 42a or the base-side position misalignment prevention part 51, for example, if it is considered the case where the wafer 200 is out of position to the base side, it is necessary that (e-f) is 5 mm or greater.

In this way, the backside peripheral part of the wafer 200 is prevented from making contact with the substrate placing plate 40 because a non-crystallized chemical vapor deposition (CVD) film is formed on the backside peripheral part of the wafer 200 during a CVD film forming process. Since such a non-crystallized CVD film is fragile, if the non-crystallized CVD film makes contact with the substrate placing plate 40, the non-crystallized CVD film may be stripped and generate particles. The International Sematech Manufacturing Initiative (ISMI) specifies that a wafer should not be supported at a position within 3 mm from the periphery of the wafer.

In addition, as shown by partial sectional views of FIG. 6A to FIG. 6F, in the tip-side substrate placing parts 44a and 44b and the base-side substrate placing parts 47a and 47b, all edges adjacent to wafer contact surfaces are rounded. For example, the edges 61 and 62 shown in FIG. 6A and the edges 63 and 64 shown in FIG. 6B are rounded. Owing this structure, the backside of the wafer 200 can be prevented from being scratched.

Although an explanation has been given on the case of using a substrate transfer machine of a vertical apparatus in the above-described embodiment, the present invention can also be applied to a substrate transfer machine of a single-wafer type apparatus.

The present invention is not limited to the above-described embodiment, but various changes and modifications may be made in the present invention without departing from the scope of the invention.

As described above, when a wafer is placed on the substrate placing plate, the backside peripheral part of the wafer can be prevented from making contact with the substrate placing plate.

(Supplementary Note) The present invention also includes the following embodiments.

(Supplementary Note 1) According to an embodiment of the present invention, there is provided a substrate processing apparatus comprising: a process chamber configured to accommodate a substrate and perform a heat treatment on the substrate; and a substrate transfer machine configured to carry the substrate into the process chamber in a state where the substrate is placed on a substrate placing plate,

wherein the substrate placing plate comprises at least three substrate placing parts, and

the at least three substrate placing parts are located on the same horizontal plane, and in a state where the at least three substrate placing parts are located at a top side of the substrate placing plate, top surfaces of the at least three substrate placing parts are higher than a surface of the substrate placing plate surrounded by the at least three substrate placing parts and are higher than all peripheral surfaces of the at least three substrate placing parts.

If the substrate processing apparatus is configured as described above, when a wafer is placed on the substrate placing plate, the backside peripheral part of the wafer can be prevented from making contact with the substrate placing plate.

(Supplementary Note 2) In the substrate processing apparatus of Supplementary Note 1, the substrate placing parts may comprise two substrate placing parts disposed at a tip side of the substrate placing plate and two substrate placing parts disposed at a base side of the substrate placing plate, and

wherein a distance between the two substrate placing parts disposed at the base side is greater than a distance between the two substrate placing parts disposed at the tip side.

If the substrate processing apparatus is configured as described above, the amount of deflection of a wafer can be reduced when the wafer is placed on the substrate placing plate, and misalignment of the wafer can be prevented when the substrate placing plate on which the wafer is placed is moved.

(Supplementary Note 3) In the substrate processing apparatus of Supplementary Note 2 or 3, each of the substrate placing parts may comprise a substrate placing surface for placing a substrate thereon and a surface rising from a surface of the substrate placing plate to the substrate placing surface, and an edge between the rising surface and the substrate placing surface may be rounded.

If the substrate processing apparatus is configured as described above, when a wafer is placed on the substrate placing parts, the wafer may not be scratched.

(Supplementary Note 4) In the substrate processing apparatus of Supplementary Notes 1 to 3, the substrate placing plate may be divided into two arms having a sheet shape and extending from the tip side to the base side of the substrate placing plate, and outer sides of the two arms may be parallel with each other.

If the substrate processing apparatus is configured as described above, the substrate placing plate can be easily inserted into a pod.

(Supplementary Note 5) In the substrate processing apparatus of Supplementary Note 4, the width of the base side where the base-side substrate placing parts are located is greater than the width between the outer sides of the two arms.

If the substrate processing apparatus is configured as described above, the substrate placing plate can be easily inserted into a pod.

(Supplementary Note 6) According to another embodiment of the present invention, there is provided a substrate processing apparatus comprising:

a boat configured to support a plurality of substrates with four support parts for each of the substrates;

a process chamber configured to accommodate the boat and perform a heat treatment on the substrates held in the boat; and

a substrate transfer machine comprising a substrate placing plate to place a substrate thereon and carry the substrate to the boat,

wherein the substrate placing plate on which a substrate is placed is insertable between front-side two of the four support parts of the boat which are located close to the substrate transfer machine,

wherein the substrate placing plate comprises at least two substrate placing parts at a base side and at least two substrate placing parts at a tip side, and a distance between the two substrate placing parts disposed at the base side is greater than a distance between the front-side two of the support parts of the boat.

If the substrate processing apparatus is configured as described above, the amount of deflection of a wafer can be reduced when the wafer is placed on the substrate placing plate, and misalignment of the wafer can be prevented when the substrate placing plate on which the wafer is placed is moved.

What is claimed is:

1. A substrate processing apparatus comprising:
a process chamber configured to accommodate a substrate and perform a heat treatment on the substrate; and
a substrate transfer machine configured to carry the substrate into the process chamber in a state where the substrate is placed on a substrate placing plate,
wherein the substrate placing plate comprises at least three substrate placing parts, and
the at least three substrate placing parts are located on the same horizontal plane, and in a state where the at least three substrate placing parts are located at a top side of the substrate placing plate, top surfaces of the at least three substrate placing parts are higher than a surface of the substrate placing plate surrounded by the at least three substrate placing parts and are higher than all peripheral surfaces of the at least three substrate placing parts.

2. The substrate processing apparatus of claim 1, wherein the substrate placing parts comprise two substrate placing parts disposed at a tip side of the substrate placing plate and two substrate placing parts disposed at a base side of the substrate placing plate, and
a distance between the two substrate placing parts disposed at the base side is greater than a distance between the two substrate placing parts disposed at the tip side.

3. A substrate processing apparatus comprising:
a boat configured to support a plurality of substrates with four support parts for each of the substrates;
a process chamber configured to accommodate the boat and perform a heat treatment on the substrates held in the boat; and
a substrate transfer machine comprising a substrate placing plate to place a substrate thereon and carry the substrate to the boat,
wherein the substrate placing plate on which a substrate is placed is insertable between front-side two of the four support parts of the boat which are located close to the substrate transfer machine,
wherein the substrate placing plate comprises at least two substrate placing parts at a base side and at least two substrate placing parts at a tip side, and a distance between the two substrate placing parts disposed at the base side is greater than a distance between the front-side two of the support parts of the boat.
